(19) United States
(12) Patent Application Publication
(10) Pub. No.: US 2017/0031822 A1
(43) Pub. Date: Feb. 2, 2017

(54) CONTROL METHOD AND ELECTRONIC DEVICE

(71) Applicants: BEIJING LENOVO SOFTWARE LTD., Beijing (CN); LENOVO (BEIJING) LIMITED, Beijing (CN)

(72) Inventors: Qian MA, Beijing (CN); Chen YANG, Beijing (CN)

(73) Assignees: LENOVO (BEIJING) LIMITED, Beijing (CN); BEIJING LENOVO SOFTWARE LTD., Beijing (CN)

(21) Appl. No.: 14/851,557

(22) Filed: Sep. 11, 2015

(30) Foreign Application Priority Data
Jul. 27, 2015 (CN) 201510446976.6

(51) Int. Cl. G06F 12/08; G11C 7/10

(52) U.S. Cl. CPC G06F 12/0831; G11C 7/1072; G06F 12/0811; G06F 2212/283; G06F 2212/621

(57) ABSTRACT

The present disclosure provides a control method and an electronic device. The electronic device detects and obtains operation parameters associated with a first operation on the electronic device; determines an operation type based on the operation parameter; and generates an adjustment scheme for a first cache region and/or a second cache region of a storage unit based on the operation type to adjust the first cache region and/or the second cache region, so as to change a ratio between their storage spaces.

### TECHNICAL FIELD

The present disclosure relates to electronic control technology, and more particularly, to a control method and an electronic device.

### BACKGROUND

A Solid State Drive (SSD) typically has a Dynamic Random Access Memory (DRAM) for buffering data and storing a mapping table and other important data. The DRAM is mainly used as a data cache that can accept data update operations generated in a load in real time and reduce the number of times a flash memory is accessed by means of direct memory operations.

However, a data cache is typically divided into a read region and a write region and the sizes of the read region and the write region are fixed, which greatly limits the use efficiency and hit rate of the data cache.

### SUMMARY

In view of this, it is an object of the present disclosure to provide a control method and an electronic device, capable of solving the problem in the existing techniques.

According to an embodiment of the present disclosure, a control method is provided. The method is applied in an electronic device and comprises: detecting a first operation on the electronic device; obtaining operation parameters associated with the first operation; determining an operation type based on the operation parameter; generating an adjustment scheme for a first cache region and/or a second cache region of a storage unit based on the operation type; and adjusting the first cache region and/or the second cache region in accordance with the adjustment scheme, so as to change a ratio between their storage spaces.

In an embodiment, the first cache region is used for a first data operation and the second cache region is used for a second data operation different from the first data operation.

In an embodiment, the step of determining an operation type based on the operation parameters comprises: determining the operation type as the first data operation when the operation parameters indicate that the first operation is a reading operation; and determining the operation type as the second data operation when the operation parameters indicate that the first operation is a writing operation.

In an embodiment, the step of generating an adjustment scheme for a first cache region and/or a second cache region of a storage unit based on the operation type comprises: generating a first adjustment scheme as the adjustment scheme for the first cache region and/or the second cache region of the storage unit when the operation type is the first data operation. Accordingly, the step of adjusting the first cache region and/or the second cache region in accordance with the adjustment scheme comprises: increasing the first cache region of the storage unit by a first predetermined value and/or decreasing the second cache region of the storage unit by a second predetermined value, in accordance with the first adjustment scheme.

In an embodiment, the method further comprises, when the operation type is the first data operation: detecting whether the first data operation has reached a predetermined read threshold to obtain a first detection result; and generating the first adjustment scheme as the adjustment scheme for the first cache region and/or the second cache region of the storage unit when the first detection result indicates that the first data operation has reached the predetermined read threshold.

In an embodiment, the step of generating an adjustment scheme for a first cache region and/or a second cache region of a storage unit based on the operation type comprises: generating a second adjustment scheme as the adjustment scheme for the first cache region and/or the second cache region of the storage unit when the operation type is the second data operation. Accordingly, the step of adjusting the first cache region and/or the second cache region in accordance with the adjustment scheme comprises: decreasing the first cache region of the storage unit by a third predetermined value and/or increasing the second cache region of the storage unit by a fourth predetermined value, in accordance with the second adjustment scheme.

In an embodiment, the method further comprises, when the operation type is the second data operation: detecting whether the second data operation has reached a predetermined write threshold to obtain a second detection result; and generating the second adjustment scheme as the adjustment scheme for the first cache region and/or the second cache region of the storage unit when the second detection result indicates that the second data operation has reached the predetermined write threshold.

According to another embodiment of the present disclosure, an electronic device is provided. The electronic device comprises: a storage unit, including a first cache region and a second cache region; at least one processor; a detecting module executable by the at least one processor and configured to detect a first operation on the electronic device; an obtaining module executable by the at least one processor and configured to obtain operation parameters associated with the first operation; a determining module executable by the at least one processor and configured to determine an operation type based on the operation parameter; a generating module executable by the at least one processor and configured to generate an adjustment scheme for a first cache region and/or a second cache region of a storage unit based on the operation type; and an adjusting module executable by the at least one processor and configured to adjust the first cache region and/or the second cache region in accordance with the adjustment scheme, so as to change a ratio between their storage spaces.

In an embodiment, the first cache region is used for a first data operation and the second cache region is used for a second data operation different from the first data operation.

In an embodiment, the determining module comprises: a first determining sub-module executable by the at least one processor and configured to determine the operation type as the first data operation when the operation parameters indicate that the first operation is a reading operation; and a second determining sub-module executable by the at least one processor and configured to determine the operation type as the second data operation when the operation parameters indicate that the first operation is a writing operation.

In an embodiment, the generating module is configured to generate a first adjustment scheme as the adjustment scheme for the first cache region and/or the second cache region of the storage unit when the operation type is the first data operation. Accordingly, the adjusting module is configured to increase the first cache region of the storage unit by a first predetermined value and/or decrease the second cache region of the storage unit by a second predetermined value, in accordance with the first adjustment scheme.

In an embodiment, the detecting module is further configured to detect, when the operation type is the first data operation, whether the first data operation has reached a predetermined read threshold to obtain a first detection result, and the generating module is further configured to generate the first adjustment scheme as the adjustment scheme for the first cache region and/or the second cache region of the storage unit when the first detection result indicates that the first data operation has reached the predetermined read threshold.

In an embodiment, the generating module is configured to generate a second adjustment scheme as the adjustment scheme for the first cache region and/or the second cache region of the storage unit when the operation type is the second data operation. Accordingly, the adjusting module is configured to decrease the first cache region of the storage unit by a third predetermined value and/or increase the second cache region of the storage unit by a fourth predetermined value, in accordance with the second adjustment scheme.

In an embodiment, the detecting module is further configured to detect, when the operation type is the second data operation, whether the second data operation has reached a predetermined write threshold to obtain a second detection result; and the generating module is further configured to generate the second adjustment scheme as the adjustment scheme for the first cache region and/or the second cache region of the storage unit when the second detection result indicates that the second data operation has reached the predetermined write threshold.

In an embodiment, the storage unit is a Dynamic Random Access Memory (DRAM).

In an embodiment, the DRAM is in a Solid State Drive (SSD).

### BRIEF DESCRIPTION OF THE DRAWINGS

FIG. 1 is a flowchart illustrating a control method according to a first embodiment of the present disclosure;

FIG. 2 is a flowchart illustrating a control method according to a second embodiment of the present disclosure;

FIG. 3 is a schematic diagram showing a conventional distribution of DRAM in an SSD;

FIGS. 4-1˜4-3 are schematic diagrams each showing a distribution of DRAM in an SSD after adjustment in accordance with a first adjustment scheme in an embodiment of the present disclosure;

FIG. 5 is a flowchart illustrating a control method according to a third embodiment of the present disclosure;

FIGS. 6-1˜6-3 are schematic diagrams each showing a distribution of DRAM in an SSD after adjustment in accordance with a second adjustment scheme in an embodiment of the present disclosure;

FIG. 7 is a flowchart illustrating a control method according to a fourth embodiment of the present disclosure;

FIG. 8 is a flowchart illustrating a control method according to a fifth embodiment of the present disclosure;

FIG. 9 is a schematic diagram showing a structure of an electronic device according to an embodiment of the present disclosure; and

FIG. 10 is a schematic diagram showing a structure of a determining module according to an embodiment of the present disclosure.

### DETAILED DESCRIPTION OF THE EMBODIMENTS

In the following, the present disclosure will be explained in further detail with reference to the figures and embodiments.

### First Method Embodiment

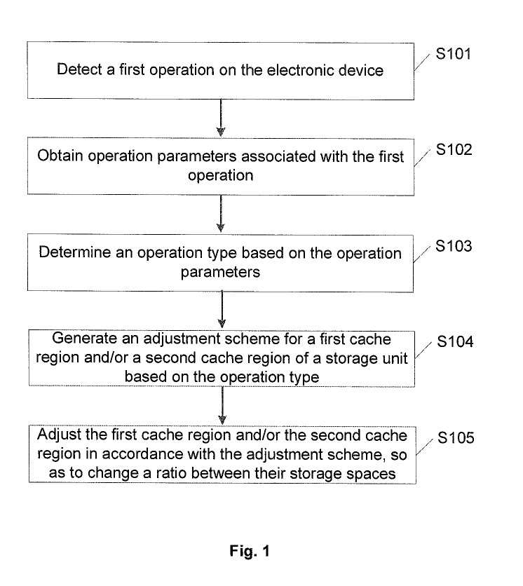

FIG. 1 is a flowchart illustrating a control method according to a first embodiment of the present disclosure. As shown in FIG. 1, the control method can be applied in an electronic device and include the following steps.

At step S101, a first operation on the electronic device is detected. At step S102, operation parameters associated with the first operation is obtained.

Here, the first operation can be a physical key operation or a virtual key operation performed by a user on a keyboard, a mouse or a touch screen. The first operation may include a reading operation such as watching video, listening to music or viewing materials, or a writing operation such as modifying documents or updating charts. Here the video, music, materials, documents and charts are data information stored to a storage unit in advance.

In particular, the electronic device can detect a physical key operation or a virtual key operation performed by a user on a keyboard, a mouse or a touch screen, so as to obtain the operation parameters associated with the first operation.

The operation parameters may include watching, listening, viewing, modifying and updating, among which watching, listening and viewing may indicate that the first operation is a reading operation and modifying and updating may indicate that the first operation is a writing operation.

Here, the electronic device can be a mobile phone, a Personal Computer (PC), a tablet computer or a Personal Digital Assistant (PDA) applied in the field of communications, or a smart device applied in fields such as military, vehicle, engineering control, video surveillance, network monitor, network terminal, electrical power, medical treatment, aviation and navigation.

At step S103, an operation type is determined based on the operation parameter.

In particular, the electronic device determining an operation type based on the operation parameters may include determining the operation type as the first data operation when the operation parameters indicate that the first operation is a first data operation; and determining the operation type as the second data operation when the operation parameters indicate that the first operation is a second data operation different from the first data operation.

At step S104, an adjustment scheme for a first cache region and/or a second cache region of a storage unit is generated based on the operation type.

Here, the first cache region is used for the first data operation and the second cache region is used for the second data operation.

Here, the storage unit can be a DRAM which can be in an SSD. The SSD can be provided within the electronic device, or can be connected to the electronic device via an interface. In order to utilize the advantage of the SSD in its fast read/write speed as much as possible, it is typically preferred to provide the SSD within the electronic device.

In particular, depending on the operation type, the electronic device may generate different adjustment schemes for the first cache region and/or the second cache region in the storage unit.

At step S105, the first cache region and/or the second cache region is/are adjusted in accordance with the adjustment scheme, so as to change a ratio between their storage spaces.

In particular, the electronic device adjusts the first cache region and/or the second cache region of the storage unit in accordance with the adjustment scheme, so as to change a ratio between their storage spaces

In an example, when the operation type is the first data operation, that is, when the operation parameters indicate that the first operation is a reading operation, the ratio between the storage spaces of the first and second cache regions can be changed by increasing the ratio of the first cache region for the first data operation and/or decreasing the ratio of the second cache region for the second data operation.

In another example, when the operation type is the second data operation, that is, when the operation parameters indicate that the first operation is a writing operation, the ratio between the storage spaces of the first and second cache regions can be changed by decreasing the ratio of the first cache region for the first data operation and/or increasing the ratio of the second cache region for the second data operation.

With the control method according to the embodiment of the present disclosure, the electronic device detects and obtains operation parameters associated with a first operation on the electronic device; determines an operation type based on the operation parameter; and generates an adjustment scheme for a first cache region and/or a second cache region of a storage unit based on the operation type to adjust the first cache region and/or the second cache region, so as to change a ratio between their storage spaces. In this way, it is possible to solve the problem associated with the fixed ratio between the first cache region and the second cache region of the storage unit, thereby effectively improving the hit rate of the cache regions, the use efficiency of the storage unit and the user experience.

### Second Method Embodiment

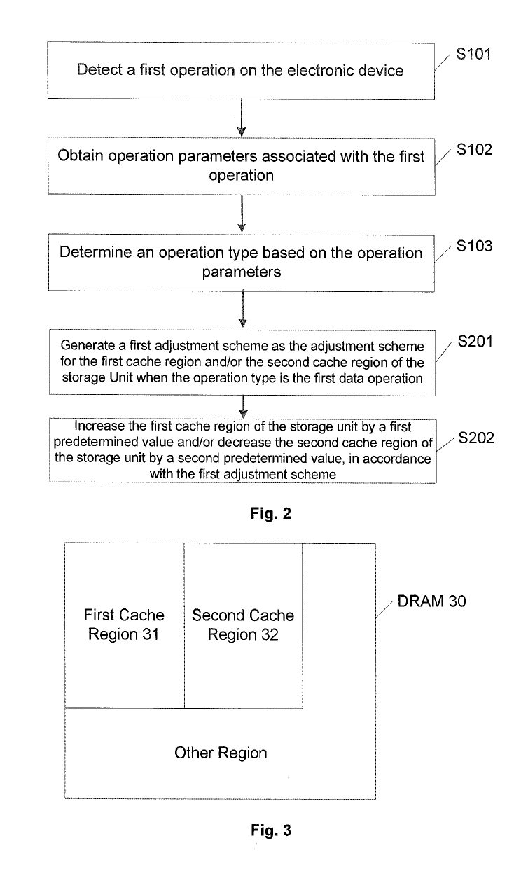

FIG. 2 is a flowchart illustrating a control method according to a second embodiment of the present disclosure. As shown in FIG. 2, the control method can be applied in an electronic device and include the following steps.

At step S101, a first operation on the electronic device is detected. At step S102, operation parameters associated with the first operation is obtained.

At step S103, an operation type is determined based on the operation parameter.

The steps S101-S103 in this embodiment are similar to the steps S101-S103 in the first embodiment and details thereof will be omitted here.

At step S201, when the operation type is a first data operation, a first adjustment scheme is generated as an adjustment scheme for a first cache region and/or a second cache region of a storage unit.

Here, when the operation parameters indicate that the first operation is a reading operation, the operation type is determined as a first data operation. When the operation type is the first data operation, the use scenario of the storage unit is a data read state corresponding to the first data operation. In this case, the electronic device generates a first adjustment scheme to increase the first cache region of the storage unit by a first predetermined value and/or decrease the second cache region of the storage unit by a second predetermined value.

At step S202, in accordance with the first adjustment scheme, the first cache region of the storage unit is increased by the first predetermined value and/or the second cache region of the storage unit is decreased by the second predetermined value.

In particular, in accordance with the first adjustment scheme, the electronic device can increase the first cache region of the storage unit by the first predetermined value, or decrease the second cache region of the storage unit by the second predetermined value, or both.

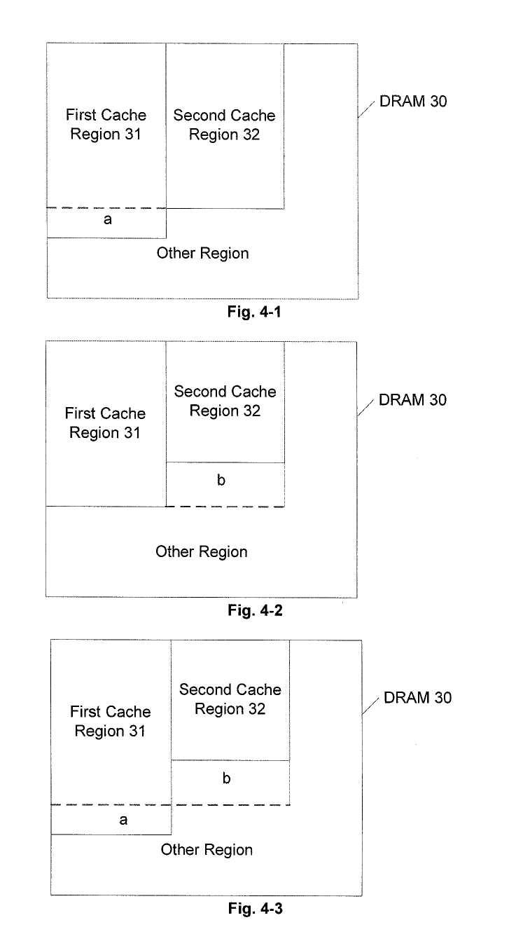

In an example, as shown in FIG. 3, for a conventional DRAM 30 in a SSD, when the DRAM 30 is used as a data cache, the ratio between a first cache region 31 for a first data operation (i.e., a reading operation) and a second cache region 32 for a second data operation (i.e., a writing operation) in the data cache is fixed. It is to be noted here that the other regions than the cache regions are mainly used for storing mapping tables and other important data. FIGS. 4-1˜4-3 each show a distribution effect of the DRAM of the storage unit after adjustment in accordance with the first adjustment scheme in the embodiment of the present disclosure to increase the first cache region of the storage unit by the first predetermined value a, and/or decrease the second cache region of the storage unit by the second predetermined value b. As shown in FIGS. 4-1˜4.3, when the operation type is the first data operation, i.e., when the use scenario of the storage unit is a data read state corresponding to the first data operation, the ratio of the first cache region 31 for the first data operation is greater than that of the second cache region 32 for the second data operation, such that, when the storage unit is used for caching data, the probability of reading data from the first cache region 31 can be increased and the probability of writing data to the second cache region 32 can be decreased, thereby increasing the hit rate.

With the control method according to the embodiment of the present disclosure, the electronic device determines an operation type as a first data operation based on operation parameters; generates a first adjustment scheme as an adjustment scheme for a first cache region and/or a second cache region in a storage unit; and increases the first cache region of the storage unit by a first predetermined value and/or decreases the second cache region of the storage unit by a second predetermined value, in accordance with the first adjustment scheme, so as to change a ratio between their storage spaces. In this way, it is possible to solve the problem associated with the fixed ratio between the first cache region and the second cache region of the storage unit, thereby effectively improving the hit rate of the cache regions, the use efficiency of the storage unit and the user experience.

### Third Method Embodiment

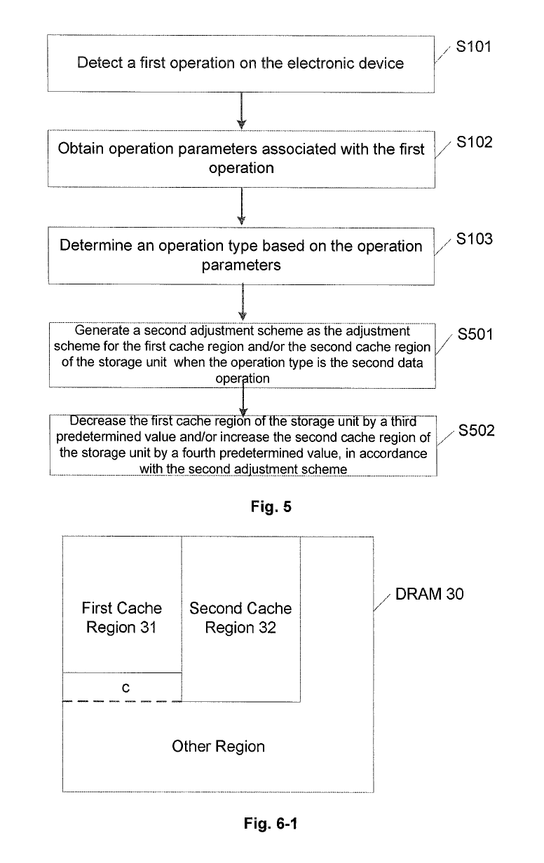

FIG. 5 is a flowchart illustrating a control method according to a third embodiment of the present disclosure. As shown in FIG. 5, the control method can be applied in an electronic device and include the following steps.

At step S101, a first operation on the electronic device is detected. At step S102, operation parameters associated with the first operation is obtained.

At step S103, an operation type is determined based on the operation parameter.

The steps S101-S103 in this embodiment are similar to the steps S101-S103 in the first embodiment and details thereof will be omitted here.

At step S501, when the operation type is a second data operation, a second adjustment scheme is generated as an adjustment scheme for a first cache region and/or a second cache region of a storage unit.

Here, when the operation parameters indicate that the first operation is a writing operation, the operation type is determined as a second data operation. When the operation type is the second data operation, the use scenario of the storage unit is a writing state corresponding to the second data operation. In this case, the electronic device generates a second adjustment scheme to decrease the first cache region of the storage unit by a third predetermined value and/or increase the second cache region of the storage unit by a fourth predetermined value.

At step S502, in accordance with the second adjustment scheme, the first cache region of the storage unit is decreased by the third predetermined value and/or the second cache region of the storage unit is increased by the fourth predetermined value.

In particular, in accordance with the second adjustment scheme, the electronic device can decrease the first cache region of the storage unit by the third predetermined value, or increase the second cache region of the storage unit by the fourth predetermined value, or both.

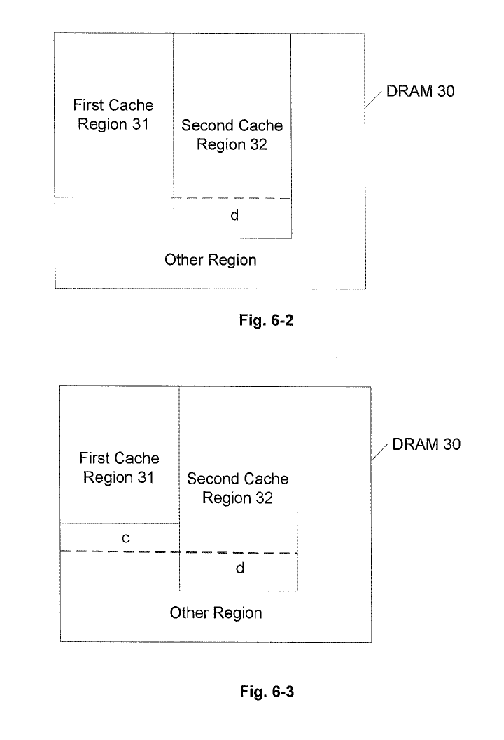

In an example, as shown in FIG. 3, for a conventional DRAM 30 in a SSD, when the DRAM 30 is used as a data cache, the ratio between a first cache region 31 for a first data operation (i.e., a reading operation) and a second cache region 32 for a second data operation (i.e., a writing operation) in the data cache is fixed. It is to be noted here that the other regions than the cache regions are mainly used for storing mapping tables and other important data. FIGS. 6-1˜6-3 each show a distribution effect of the DRAM of the storage unit after adjustment in accordance with the second adjustment scheme in the embodiment of the present disclosure to decrease the first cache region of the storage unit by the third predetermined value c, and/or increase the second cache region of the storage unit by the fourth predetermined value d. As shown in FIGS. 6-1˜6.3, when the operation type is the second data operation, i.e., when the use scenario of the storage unit is a writing state corresponding to the second data operation, the ratio of the first cache region 31 for the first data operation is smaller than that of the second cache region 32 for the second data operation, such that, when the storage unit is used for caching data, the probability of reading data from the first cache region 31 can be decreased and the probability of writing data to the second cache region 32 can be increased, thereby increasing the hit rate.

With the control method according to the embodiment of the present disclosure, the electronic device determines an operation type as a second data operation based on operation parameters; generates a second adjustment scheme as an adjustment scheme for a first cache region and/or a second cache region of a storage unit; and decreases the first cache region of the storage unit by a third predetermined value and/or increases the second cache region of the storage unit by a fourth predetermined value, in accordance with the second adjustment scheme, so as to change a ratio between their storage spaces. In this way, it is possible to solve the problem associated with the fixed ratio between the first cache region and the second cache region of the storage unit, thereby effectively improving the hit rate of the cache regions, the use efficiency of the storage unit and the user experience.

### Fourth Method Embodiment

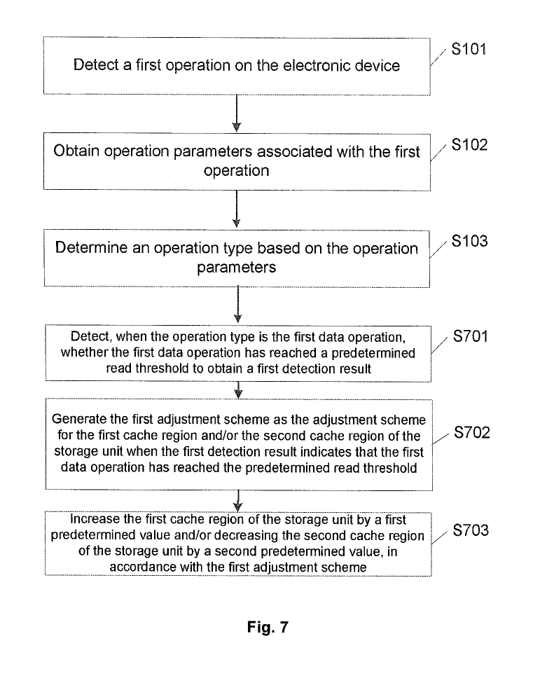

FIG. 7 is a flowchart illustrating a control method according to a fourth embodiment of the present disclosure. As shown in FIG. 7, the control method can be applied in an electronic device and include the following steps.

At step S101, a first operation on the electronic device is detected. At step S102, operation parameters associated with the first operation is obtained.

At step S103, an operation type is determined based on the operation parameter.

The steps S101-S103 in this embodiment are similar to the steps S101-S103 in the first embodiment and details thereof will be omitted here.

At step S701, when the operation type is a first data operation, it is detected whether the first data operation has reached a predetermined read threshold to obtain a first detection result.

Here, when the operation parameters indicate that the first operation is a reading operation, the operation type is determined as a first data operation. When the operation type is the first data operation, the use scenario of the storage unit is a data read state corresponding to the first data operation.

The predetermined read threshold here is a read rate threshold required when the use scenario of the storage unit is the data read state corresponding to the first data operation. The predetermined read threshold can be typically determined based on various factors such as the performance of the SSD to which the storage unit belongs and the user's requirement on the read rate of the electronic device.

In particular, when the electronic device determines the operation type as the first data operation, it further detects whether the first data operation has reached a predetermined read threshold to obtain a first detection result. When the first data operation has reached the predetermined read threshold, it determines to adjust the ratio(s) of the first cache region and/or the second cache region, thereby proceeding with the next step S702. When the first detection result indicates that the first data operation has not reached the predetermined read threshold, i.e., lower than the predetermined read threshold, it can be determined that the ratio(s) of the first cache region and/or the second cache region of the storage unit can satisfy the fundamental requirement for the storage unit to be used as the data cache. Hence, there is no need to adjust the ratio(s) of the first cache region and/or the second cache region and the process can be terminated immediately.

At step S702, when the first detection result indicates that the first data operation has reached the predetermined read threshold, the first adjustment scheme is generated as the adjustment scheme for the first cache region and/or the second cache region of the storage unit.

In particular, after obtaining the first detection result indicating that the first data operation has reached the predetermined read threshold, the electronic device generates the first adjustment scheme to increase the first cache region of the storage unit by a first predetermined value and/or decrease the second cache region of the storage unit by a second predetermined value.

At step S703, in accordance with the first adjustment scheme, the first cache region of the storage unit is increased by the first predetermined value and/or the second cache region of the storage unit is decreased by the second predetermined value.

The step S703 in this embodiment is similar to the step S202 in the second embodiment and details thereof will be omitted here.

With the control method according to the embodiment of the present disclosure, the electronic device determines an operation type as a first data operation based on operation parameters and further detects whether the first data operation has reached a predetermined read threshold to obtain a first detection result. When the first detection result indicates that the first data operation has reached the predetermined read threshold, the first adjustment scheme is generated as the adjustment scheme for the first cache region and/or the second cache region of the storage unit. In accordance with the first adjustment scheme, the first cache region of the storage unit is increased by a first predetermined value and/or the second cache region of the storage unit is decreased by a second predetermined value, thereby changing the ratio between the storage spaces of the first and second cache regions. In this way, the first adjustment scheme is generated as the adjustment scheme for the first cache region and/or the second cache region of the storage unit only when the first data operation has reached the predetermined read threshold. Therefore, in addition to solving the problem associated with the fixed ratio between the first cache region and the second cache region of the storage unit, the timing for adjusting the ratio(s) of the first cache region and/or the second cache region can be effectively controlled, so as to effectively improve the hit rate of the cache regions, the use efficiency of the storage unit and the user experience.

### Fifth Method Embodiment

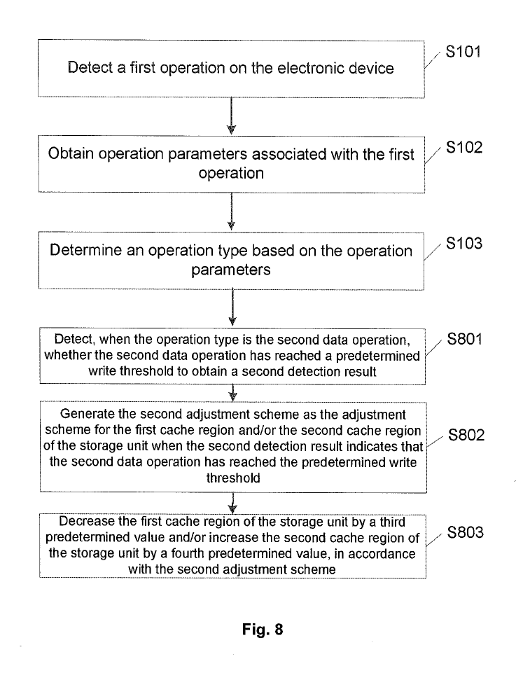

FIG. 8 is a flowchart illustrating a control method according to a fifth embodiment of the present disclosure. As shown in FIG. 8, the control method can be applied in an electronic device and include the following steps.

At step S101, a first operation on the electronic device is detected. At step S102, operation parameters associated with the first operation is obtained.

At step S103, an operation type is determined based on the operation parameter.

The steps S101-S103 in this embodiment are similar to the steps S101-S103 in the first embodiment and details thereof will be omitted here.

At step S801, when the operation type is a second data operation, it is detected whether the second data operation has reached a predetermined write threshold to obtain a second detection result.

Here, when the operation parameters indicate that the first operation is a writing operation, the operation type is determined as a second data operation. When the operation type is the second data operation, the use scenario of the storage unit is a writing state corresponding to the second data operation.

The predetermined write threshold here is a write rate threshold required when the use scenario of the storage unit is the writing state corresponding to the second data operation. The predetermined write threshold can be typically determined based on various factors such as the performance of the SSD to which the storage unit belongs and the user's requirement on the write rate of the electronic device.

In particular, when the electronic device determines the operation type as the second data operation, it further detects whether the second data operation has reached a predetermined write threshold to obtain a second detection result. When the second data operation has reached the predetermined write threshold, it determines to adjust the ratio(s) of the first cache region and/or the second cache region, thereby proceeding with the next step S802. When the second detection result indicates that the second data operation has not reached the predetermined write threshold, i.e., lower than the predetermined write threshold, it can be determined that the ratio(s) of the first cache region and/or the second cache region of the storage unit can satisfy the fundamental requirement for the storage unit to be used as the data cache. Hence, there is no need to adjust the ratio(s) of the first cache region and/or the second cache region and the process can be terminated immediately.

At step S802, when the second detection result indicates that the second data operation has reached the predetermined write threshold, the second adjustment scheme is generated as the adjustment scheme for the first cache region and/or the second cache region of the storage unit.

In particular, after obtaining the second detection result indicating that the second data operation has reached the predetermined write threshold, the electronic device generates the second adjustment scheme to decrease the first cache region of the storage unit by a third predetermined value and/or increase the second cache region of the storage unit by a fourth predetermined value.

At step S803, in accordance with the second adjustment scheme, the first cache region of the storage unit is decreased by the third predetermined value and/or the second cache region of the storage unit is increased by the fourth predetermined value.

The step S803 in this embodiment is similar to the step S502 in the third embodiment and details thereof will be omitted here.

With the control method according to the embodiment of the present disclosure, the electronic device determines an operation type as a second data operation based on operation parameters and further detects whether the second data operation has reached a predetermined write threshold to obtain a second detection result. When the second detection result indicates that the second data operation has reached the predetermined write threshold, the second adjustment scheme is generated as the adjustment scheme for the first cache region and/or the second cache region of the storage unit. In accordance with the second adjustment scheme, the first cache region of the storage unit is decreased by a third predetermined value and/or the second cache region of the storage unit is increased by a fourth predetermined value, thereby changing the ratio between the storage spaces of the first and second cache regions. In this way, the second adjustment scheme is generated as the adjustment scheme for the first cache region and/or the second cache region of the storage unit only when the second data operation has reached the predetermined write threshold. Therefore, in addition to solving the problem associated with the fixed ratio between the first cache region and the second cache region of the storage unit, the timing for adjusting the ratio(s) of the first cache region and/or the second cache region can be effectively controlled, so as to effectively improve the hit rate of the cache regions, the use efficiency of the storage unit and the user experience.

Product Embodiment

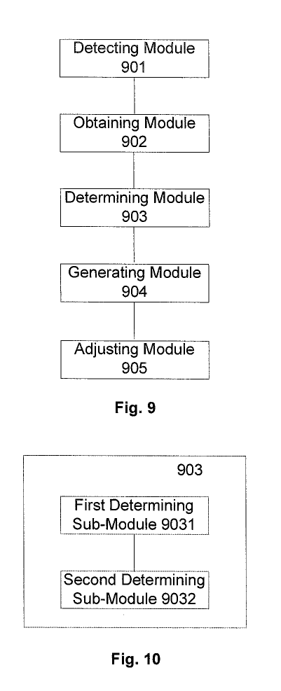

FIG. 9 is a schematic diagram showing a structure of an electronic device according to an embodiment of the present disclosure. As shown in FIG. 9, the electronic device includes a storage unit and at least one processor (not shown). The electronic device further includes a detecting module 901, an obtaining module 902, a determining module 903, a generating module 904 and an adjusting module 905, all of which are executable by the at least one processor.

The detecting module 901 is configured to detect a first operation on the electronic device.

The obtaining module 902 is configured to obtain operation parameters associated with the first operation.

The determining module 903 is configured to determine an operation type based on the operation parameter.

The generating module 904 is configured to generate an adjustment scheme for a first cache region and/or a second cache region of a storage unit based on the operation type.

Here, the first cache region is used for a first data operation and the second cache region is used for a second data operation different from the first data operation.

Here, the storage unit is typically a DRAM. In practice, the DRAM can be in an SSD.

The adjusting module 905 is configured to adjust the first cache region and/or the second cache region in accordance with the adjustment scheme, so as to change a ratio between their storage spaces.

In an embodiment, as shown in FIG. 10, the determining module 903 includes: a first determining sub-module 9031 configured to determine the operation type as the first data operation when the operation parameters indicate that the first operation is a reading operation; and a second determining sub-module 9032 configured to determine the operation type as the second data operation when the operation parameters indicate that the first operation is a writing operation.

In an embodiment, the generating module 904 is configured to generate a first adjustment scheme as the adjustment scheme for the first cache region and/or the second cache region of the storage unit when the operation type is the first data operation. Accordingly, the adjusting module 905 is configured to increase the first cache region of the storage unit by a first predetermined value and/or decrease the second cache region of the storage unit by a second predetermined value, in accordance with the first adjustment scheme.

In an embodiment, the detecting module 901 is further configured to detect, when the operation type is the first data operation, whether the first data operation has reached a predetermined read threshold to obtain a first detection result, and the generating module 904 is further configured to generate the first adjustment scheme as the adjustment scheme for the first cache region and/or the second cache region of the storage unit when the first detection result indicates that the first data operation has reached the predetermined read threshold.

In an embodiment, the generating module 904 is configured to generate a second adjustment scheme as the adjustment scheme for the first cache region and/or the second cache region of the storage unit when the operation type is the second data operation. Accordingly, the adjusting module 905 is configured to decrease the first cache region of the storage unit by a third predetermined value and/or increase the second cache region of the storage unit by a fourth predetermined value, in accordance with the second adjustment scheme.

In an embodiment, the detecting module 901 is further configured to detect, when the operation type is the second data operation, whether the second data operation has reached a predetermined write threshold to obtain a second detection result; and the generating module 904 is further configured to generate the second adjustment scheme as the adjustment scheme for the first cache region and/or the second cache region of the storage unit when the second detection result indicates that the second data operation has reached the predetermined write threshold.

In the electronic device according to the embodiments of the present disclosure, the detecting module 901, the obtaining module 902, the determining module 903, the generating module 904 and the adjusting module 905 as well as the first determining sub-module 9031 and the second determining sub-module 9032 in the determining module 903 can be implemented by a processor in the electronic device, or by a specific logic circuit in the electronic device, such as Central Processing Unit (CPU), Micro-Processing Unit (MPU), Digital Signal Processor (DSP) or Field Programmable Gate Array (FPGA).

It can be appreciated by those skilled in the art that some or all of the steps in the method embodiments as described above can be implemented by hardware following instructions of a program. Such program can be stored in a computer readable storage medium and, when executed, performs the steps of the above method embodiments. The storage medium may be any of various mediums capable of storing program codes, such as a mobile storage device, a Read Only Memory (ROM), a Random Access Memory (RAM), a magnetic disk or an optical disc.

Alternatively, when the above integrated modules of the present disclosure are implemented in software functional modules and sold or used as a standalone product, they can be stored in a computer readable storage medium. In view of this, the technical solutions according to the embodiments of the present disclosure, or in other words a part thereof which makes contribution over the prior art, can be substantially embodied in a form of software product. The computer software product can be stored in a storage medium, such as ROM/RAM, magnetic disk, optical disc and the like, containing instructions which cause a computer device (which can be a personal computer, a server, a network device or the like) to perform one or more methods according to the embodiments of the present disclosure or particular parts thereof. The storage medium may be any of various mediums capable of storing program codes, such as a mobile storage device, a ROM, a RAM, a magnetic disk or an optical disc.

While the embodiments of the present invention have been described above, the scope of the present invention is not limited thereto. Various modifications and alternatives can be made by those skilled in the art without departing from the scope of the present disclosure. These modifications and alternatives are to be encompassed by the scope of the present invention which is only defined by the claims as attached.

What is claimed is:

1. A control method, applied in an electronic device, comprising:
detecting a first operation on the electronic device;
obtaining operation parameters associated with the first operation;
determining an operation type based on the operation parameters;
generating an adjustment scheme for a first cache region and/or a second cache region of a storage unit based on the operation type; and
adjusting the first cache region and/or the second cache region in accordance with the adjustment scheme, so as to change a ratio between their storage spaces.

2. The method of claim 1, wherein the first cache region is used for a first data operation and the second cache region is used for a second data operation different from the first data operation.

3. The method of claim 2, wherein said determining an operation type based on the operation parameters comprises:
determining the operation type as the first data operation when the operation parameters indicate that the first operation is a reading operation; and
determining the operation type as the second data operation when the operation parameters indicate that the first operation is a writing operation.

4. The method of claim 3, wherein said generating an adjustment scheme for a first cache region and/or a second cache region of a storage unit based on the operation type comprises:
generating a first adjustment scheme as the adjustment scheme for the first cache region and/or the second cache region of the storage unit when the operation type is the first data operation, and
wherein said adjusting the first cache region and/or the second cache region in accordance with the adjustment scheme comprises:
increasing the first cache region of the storage unit by a first predetermined value and/or decreasing the second cache region of the storage unit by a second predetermined value, in accordance with the first adjustment scheme.

5. The method of claim 4, further comprising, when the operation type is the first data operation:
detecting whether the first data operation has reached a predetermined read threshold to obtain a first detection result; and
generating the first adjustment scheme as the adjustment scheme for the first cache region and/or the second cache region of the storage unit when the first detection result indicates that the first data operation has reached the predetermined read threshold.

6. The method of claim 3, wherein said generating an adjustment scheme for a first cache region and/or a second cache region of a storage unit based on the operation type comprises:
generating a second adjustment scheme as the adjustment scheme for the first cache region and/or the second cache region of the storage unit when the operation type is the second data operation, and
wherein said adjusting the first cache region and/or the second cache region in accordance with the adjustment scheme comprises:
decreasing the first cache region of the storage unit by a third predetermined value and/or increasing the second cache region of the storage unit by a fourth predetermined value, in accordance with the second adjustment scheme.

7. The method of claim 6, further comprising, when the operation type is the second data operation:
detecting whether the second data operation has reached a predetermined writing threshold to obtain a second detection result; and
generating the second adjustment scheme as the adjustment scheme for the first cache region and/or the second cache region of the storage unit when the second detection result indicates that the second data operation has reached the predetermined write threshold.

8. An electronic device, comprising:
a storage unit, including a first cache region and a second cache region;
at least one processor;
a detecting module executable by the at least one processor and configured to detect a first operation on the electronic device;
an obtaining module executable by the at least one processor and configured to obtain operation parameters associated with the first operation;
a determining module executable by the at least one processor and configured to determine an operation type based on the operation parameters;
a generating module executable by the at least one processor and configured to generate an adjustment scheme for a first cache region and/or a second cache region of a storage unit based on the operation type; and
an adjusting module executable by the at least one processor and configured to adjust the first cache region and/or the second cache region in accordance with the adjustment scheme, so as to change a ratio between their storage spaces.

9. The electronic device of claim 8, wherein the first cache region is used for a first data operation and the second cache region is used for a second data operation different from the first data operation.

10. The electronic device of claim 9, wherein the determining module comprises:
a first determining sub-module executable by the at least one processor and configured to determine the operation type as the first data operation when the operation parameters indicate that the first operation is a reading operation; and
a second determining sub-module executable by the at least one processor and configured to determine the operation type as the second data operation when the operation parameters indicate that the first operation is a writing operation.

11. The electronic device of claim 10, wherein
the generating module is configured to generate a first adjustment scheme as the adjustment scheme for the first cache region and/or the second cache region of the storage unit when the operation type is the first data operation, and
the adjusting module is configured to increase the first cache region of the storage unit by a first predetermined value and/or decrease the second cache region of the storage unit by a second predetermined value, in accordance with the first adjustment scheme.

12. The electronic device of claim 11, wherein
the detecting module is further configured to detect, when the operation type is the first data operation, whether the first data operation has reached a predetermined read threshold to obtain a first detection result, and
the generating module is further configured to generate the first adjustment scheme as the adjustment scheme for the first cache region and/or the second cache region of the storage unit when the first detection result indicates that the first data operation has reached the predetermined read threshold.

13. The electronic device of claim 10, wherein
the generating module is configured to generate a second adjustment scheme as the adjustment scheme for the first cache region and/or the second cache region of the storage unit when the operation type is the second data operation, and
the adjusting module is configured to decrease the first cache region of the storage unit by a third predetermined value and/or increase the second cache region of the storage unit by a fourth predetermined value, in accordance with the second adjustment scheme.

14. The electronic device of claim 13, wherein
the detecting module is further configured to detect, when the operation type is the second data operation, whether the second data operation has reached a predetermined write threshold to obtain a second detection result; and
the generating module is further configured to generate the second adjustment scheme as the adjustment scheme for the first cache region and/or the second cache region of the storage unit when the second detection result indicates that the second data operation has reached the predetermined write threshold.

15. The electronic device of claim 8, wherein the storage unit is a Dynamic Random Access Memory (DRAM).

16. The electronic device of claim 15, wherein the DRAM is in a Solid State Drive (SSD).
